(19) United States
(12) Patent Application Publication
(10) Pub. No.: US 2026/0220187 A1
(43) Pub. Date: Jul. 30, 2026

(54) TRUST SCORING OF LLM-BASED KG WITH EXPERT IN THE LOOP

(71) Applicant: Dell Products L.P., Round Rock, TX (US)

(72) Inventors: Gwenael Poitau, Montreal (CA); Ibrahim Abu Alhaol, Nepean (CA); Javad Mirzaei, Toronto (CA); Rohit Arora, San Jose, CA (US); Said Tabet, Austin, TX (US)

(21) Appl. No.: 19/039,474

(22) Filed: Jan. 28, 2025

(51) Int. Cl. G06F 16/36; G06F 11/34

(52) U.S. Cl. CPC G06F 16/367; G06F 11/34; G06F 2201/81

(57) ABSTRACT

One example method includes obtaining data concerning a configuration of a network, and passing the data to a KG (knowledge graph) creation engine, by the KG creation engine, using a KG creation LLM (large language model) to extract knowledge from the data, generating, by the KG creation LLM, a portion of a KG that represents a portion of the network, by a judge LLM, evaluating the portion of the KG to determine an extent to which the portion of the KG accurately represents the portion of the network, and updating a ground truth KG with the extracted knowledge when the portion of the KG has a confidence score that exceeds a threshold confidence score.

### COPYRIGHT AND MASK WORK NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyrights whatsoever.

### TECHNOLOGICAL FIELD OF THE DISCLOSURE

Embodiments disclosed herein generally relate to communication networks. More particularly, at least some embodiments relate to systems, hardware, software, computer-readable media, and methods, for modeling a communication network to create a model usable for various purposes such as, but not limited to, troubleshooting, communication network updates, and communication network design.

### BACKGROUND

Knowledge graphs (KG) may be used to model communication networks. A knowledge graph may comprise a visual representation of various aspects of a communication network. For example, a knowledge graph may comprise nodes that represent respective entities of a communication network. As well, a knowledge graph may comprise various edges that connect the nodes and represent relationships between the connected nodes. While such knowledge graphs have proved useful for a variety of purposes, a number of problems exist that are due in part to the use of LLMs (large language models) that are needed to model large and complex networks.

For example, building a knowledge graph using a LLM can result in varying degrees of deficiencies of the KG, at least in terms of accuracy, completeness, and reliability. Moreover, traditional evaluation methods are often insufficient in validating the credibility and quality of the generated KG, and could be labor intensive.

### BRIEF DESCRIPTION OF THE DRAWINGS

In order to describe the manner in which at least some of the advantages and features of one or more embodiments may be obtained, a more particular description of embodiments will be rendered by reference to specific embodiments thereof which are illustrated in the appended drawings. Understanding that these drawings depict only typical embodiments and are not therefore to be considered to be limiting of the scope of this disclosure, embodiments will be described and explained with additional specificity and detail through the use of the accompanying drawings.

FIG. 1 discloses a graph indicating the development of LLMs (large language models) and their components in recent years (see: Pan, S., Luo, L., Wang, Y., Chen, C., Wang, J., & Wu, X. (2023). Unifying Large Language Models and Knowledge Graphs: A Roadmap (arXiv:2306.08302). arXiv.—incorporated herein in its entirety by this reference).

FIG. 2 discloses aspects of an AFM (agentic foundation model) reference architecture.

FIG. 3 discloses an example schema, comprising a method and architecture, according to one embodiment.

FIG. 4 discloses an example computing entity configured and operable to perform any of the disclosed methods, processes, and operations.

### DETAILED DESCRIPTION OF SOME EXAMPLE EMBODIMENTS

Embodiments disclosed herein generally relate to communication networks. More particularly, at least some embodiments relate to systems, hardware, software, computer-readable media, and methods, for modeling a communication network to create a model usable for various purposes such as, but not limited to, troubleshooting, communication network updates, and communication network design.

One or more example embodiments comprise a method and/or architecture that may be used to create, and maintain, a KG that comprises a model of a communications network, examples of which include a RAN (radio access network), or O-RAN (open radio access network). The scope of this disclosure is not limited to any particular type of communications network however.

One example of a method according to an embodiment may comprise various operations, including: obtaining new data concerning a network configuration, and passing the new data to a KG creation engine which uses a KG creation LLM to extract knowledge from the data; generating, by the KG creation LLM, portions of a KG; by a judge LLM, using a trust score to evaluate the portions of the KG, where a confidence score is calculated based on a consistency of the KG portions with KG ground truth information, and relevance of the KG portions; when the confidence score is below a threshold, integrating a domain expert to evaluate and validate the KG portions; and, by the KG creation LLM, passing the extracted knowledge to a creation module that syncs the insertion of the knowledge to a ground-truth-KG when the confidence score is above the threshold.

Embodiments, such as the examples disclosed herein, may be beneficial in a variety of respects. For example, and as will be apparent from the present disclosure, one or more embodiments may provide one or more advantageous and unexpected effects, in any combination, some examples of which are set forth below. It should be noted that such effects are neither intended, nor should be construed, to limit the scope of the claims in any way. It should further be noted that nothing herein should be construed as constituting an essential or indispensable element of any embodiment. Rather, various aspects of the disclosed embodiments may be combined in a variety of ways so as to define yet further embodiments. For example, any element(s) of any embodiment may be combined with any element(s) of any other embodiment, to define still further embodiments. Such further embodiments are considered as being within the scope of this disclosure. As well, none of the embodiments embraced within the scope of this disclosure should be construed as resolving, or being limited to the resolution of, any particular problem(s). Nor should any such embodiments be construed to implement, or be limited to implementation of, any particular technical effect(s) or solution(s). Finally, it is not required that any embodiment implement any of the advantageous and unexpected effects disclosed herein.

In particular, one advantageous aspect an embodiment is that AI (artificial intelligence), implemented by one or more LLMs, may be integrated together with human input to create, modify, and/or maintain, a KG. An embodiment may employ DCF (data confidence fabric) principles, methods, and architectures to generate confidence scores with respect to an accuracy with which a KG represents the entities and relationships of a communication network. An embodiment may dynamically update, when there is sufficient confidence, a ground truth, or ground, KG, as changes occur to the underlying network. Various other advantages of one or more example embodiments will be apparent from this disclosure. In an embodiment, a communication network, or one or more portions of a communication network, may comprise a DCF, where each entity in the communication network, or communication network portion, comprises a respective node of the DCF.

### A. Example Context for One or More Embodiments

One or more embodiments may apply GenAI (generative artificial intelligence) in the context of communication network environments, such as an O-RAN for example. In this regard, AI/ML (artificial intelligence/machine learning) for communication applications and environments, such as O-RANs for example, faces various challenges, particularly in large scale deployments. Such challenges include generalization limitations, such as for new network topologies and conditions, and obtaining proper coordination of multi-vendor multi-agent solutions.

However, it may be expected that recent progress on GenAI, and LLMs in particular, will open a new era in wireless network optimization by providing unprecedented orchestration and generalization capabilities. In the longer term, GenAI may also help to shape new 6G, and subsequent, paradigms such as semantic communications.

Moreover, the approach to telecom standardization may change, possibly significantly. For example, instead of specifying granular elements of network protocols, new telecom standardization approaches may move instead towards only defining high level concepts, such as slicing for example, and leaving the lower-level granular implementation to GenAI platforms.

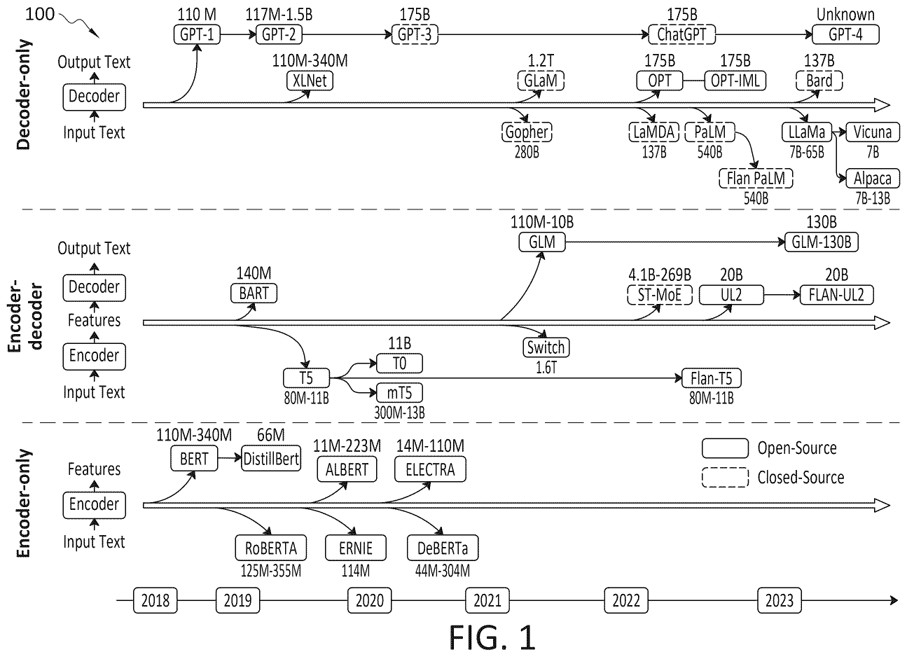

As shown in the example graph 100 disclosed in FIG. 1, the size and architecture of LLMs has progressed significantly between 2018 and 2023. This is particularly true in the areas of encoder-decoder developments, and decoder-only developments. For example, GPT-1 was a key technology in 2018, but has been overtaken by GPT-4 as of 2023. By way of contrast, the pace of development of encoder-only platforms has been somewhat slower than that of the decoder-only platforms, and slower than that of the encoder-decoder platforms.

### B. Introduction—Telco Agentic Foundation Model (AFM)

One or more embodiments may employ an AFM in the context of O-RAN operations. As used herein, a Telco Agentic Foundation Model (AFM) may comprise a GenAI module fine-tuned on telecom data which may include multiple functions to support its decision-making ability including, but not limited to, specialized AI/ML agents, knowledge base, and digital twins. One or more embodiments may employ such a GenAI module for functions including, but not limited to, prompt generation, and network configuration definition and refinement.

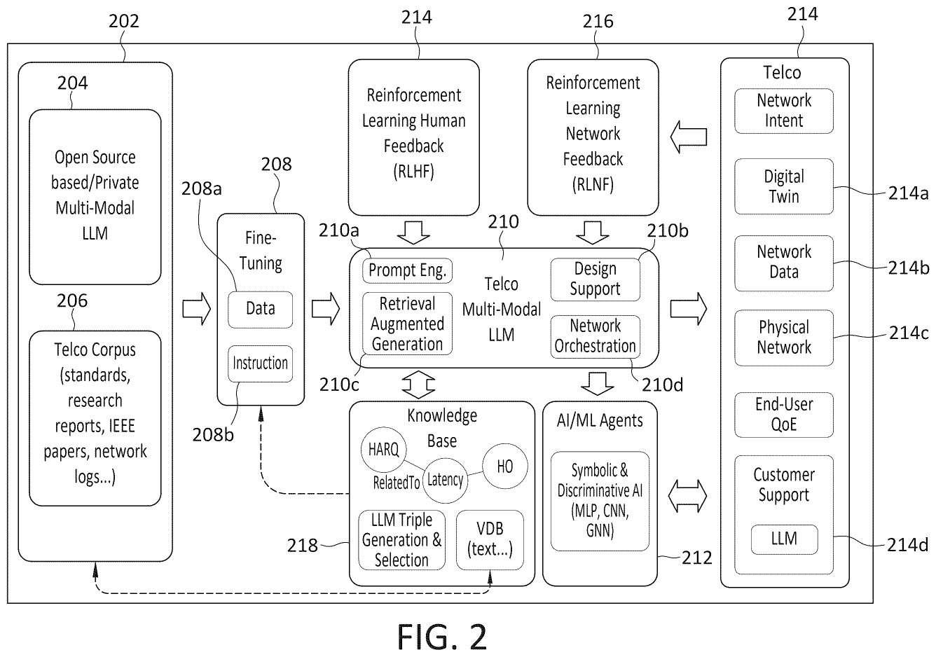

With reference now to FIG. 2, an example AFM reference architecture 200, in connection with which one or more example embodiments may be implemented, is disclosed. This example AFM reference architecture 200 describes various processes and interactions between various components and agents leveraging different knowledge bases, and implementing multiple different LLM instances tuned to achieve specific objectives. Such objectives may include, for example, network operations, network DT (digital twin) and data management, GNN (Graph Neural Network) for network optimization, customer support, and performance evaluation and training such as through the creation and use of KGs.

In more detail, the example architecture 200 may comprise various inputs 202 such as a base-level LLM 204 which may take the form of an open source based/private multi-modal LLM, and various information 206 such as a telco corpus for example. The inputs 202 may be provided to a fine-tuning module 208 that may tune the base-level LLM 204 to create a more specific LLM implementation, such as a telco, or O-RAN, multi-modal LLM 210. In addition to the inputs 202, the fine-tuning module 208 may also comprise a dataset 208a, and various instructions 208b, which may both be used in a fine tuning process.

The multi-modal LLM 210 may operate to define, and orchestrate, such as in cooperation with one or more AI/ML agents 212, one or more elements of a network configuration 214, or elements of an O-RAN. To these, and other, ends, the multi-modal LLM 210 may comprise various components, such as prompt engineering 210a, design support 210b, RAG 210c, and a network orchestration module 210d. In connection with its operations, the multi-modal LLM 210 may receive various inputs, such as reinforcement learning human feedback 214, and reinforcement learning network feedback 216, both of which may be used by the multi-modal LLM 210 to define, implement, and refine, the network configuration 214. Further, the reinforcement learning feedback, as well as historical log information concerning usage and configuration of networks, may be used to generate forecasts as to changes to the configuration, and use, of one or more private networks. As well, the multi-modal LLM 210 may draw from, and make deposits to, a knowledge base 218, concerning the operations of the multi-modal LLM 210.

Finally, the network configuration 214 may comprise various elements. Such elements may include, but are not limited to, a digital twin 214a, network data 214 b concerning network operations, events, and configurations, a physical communication network 214c, and a customer support module 214d which may comprise, for example, a virtual assistant such as a chatbot that comprises an LLM.

### C. Detailed Discussion

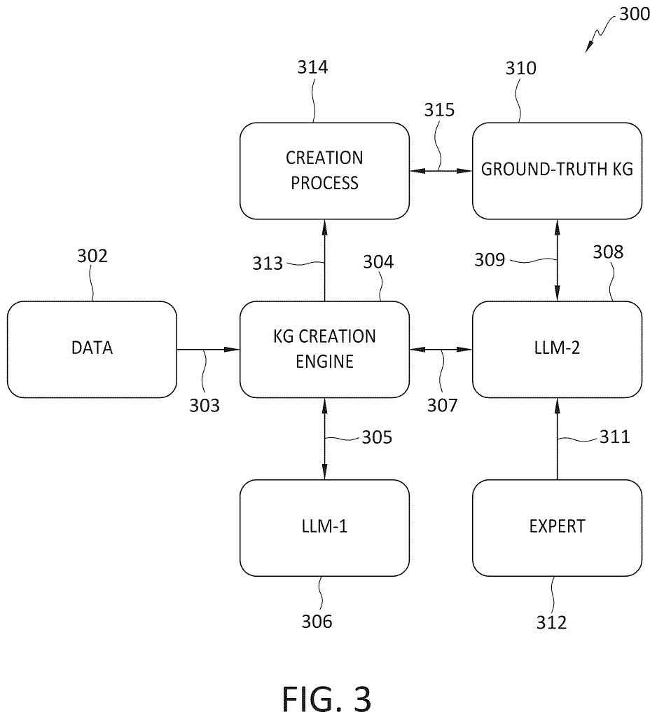

With attention now to FIG. 3, an example schema 300 is disclosed that comprises an architecture and method that may be used to create, maintain, and update, a KG that represents a communication network such as an O-RAN for example. The schema 300 may comprise a multi-faceted evaluation system and approach that combines various LLMs, such as a judge LLM and KG creation LLM, augmented by a ground truth KG and human expert input.

Among other things, a KG may enable accuracy in terms of the structure and relationships of a communication network. As well, a KG may comprise contextual network information, such as nodes and edges, that may extend over various portions of a communication network, such as regions, and specific locations, for example, and/or portions of a communication network that share one or more characteristics other than regional/locational similarity. For example, a KG may comprise nodes corresponding to all servers in a communication network, an embodiment of a KG may comprise nodes that are all located within a specified geographical area, and an embodiment of a KG may comprise nodes that all perform the same function or group of functions. Thus, a KG according to an embodiment may be defined and configured in a variety of different ways.

In an embodiment, a method for creating and updating a KG may begin with collection of data 302 concerning the structure and/or operation of a communication network. The data 302 may comprise information identifying network entities such as, but not limited to, servers, cameras both still and video, LiDAR systems, transmitters, receivers, routers, servers, computing devices of any kind, repeaters, antennas, cell phone towers, and mobile phones, for example. The data 302 may comprise information that identifies relationships between/among the network entities in a network that may include thousands, or more, nodes.

The data 302 may be passed 303 to a KG creation engine 304. The KG creation engine 304 may comprise, or access 305, a KG creation LLM 306 (LLM-1) that operates to extract, from the data 302, knowledge concerning the structure, operations, entities, and relationships, of a communication network. The extracted knowledge may then be used by the KG creation LLM 306 create one or more portions of a KG. These KG portions may then be passed 307 by the KG creation engine 304 to a judge LLM (LLM-2) 308 for evaluation.

In an embodiment, the judge LLM 308 may evaluate the KG portions using a trust, or confidence, score. This evaluation by the judge LLM 308 may comprise determining an extent to which the KG portions accurately indicate the actual configuration of the underlying communication network. In an embodiment, the judge LLM 308 may generate, or access from an external source, a confidence score for the KG portions as a whole and/or respective confidence scores for individual elements, that is, edges and nodes, of the KG portions.

In an embodiment, the judge LLM 308 may calculate one or more confidence scores by comparing the KG portions to a ground truth KG 310. In particular, the judge LLM 308 may obtain 309 ground truth information about the communication network that underlies the KG portions created by the KG creation LLM 306. The ground truth information of the ground truth KG 310 may include, but is not limited to, information that identifies the communication network entities, and the relationships between those entities. By comparing the ground truth information, that is known to be accurate, with information obtained from the KG portions, the judge LLM 308 can determine the extent to which the information from the KG portions accurately reflects the actual configuration of the underlying communication network, and may then assign respective scores to the KG portions and/or to their respective elements, that is, nodes and edges, that indicate the extent to which a KG portion, edge, or node, accurately reflects reality. For example, and using a scale of 0 to 5, a maximum confidence score of 5 may indicate that a KG portion accurately and completely reflects the associated portion of the underlying communication network, while a minimum confidence score of 0 indicates that that the KG portion bears no resemblance to the associated portion of the underlying communication network. Among other things, the use of such confidence scores may be used to drive further data 302 gathering in order to better model the communication network.

When one or more confidence scores are below a specified threshold, a domain expert 312, which may be a human and/or an AI/ML module, may be invoked 311 by the judge LLM 308 to evaluate and validate the created knowledge, that is, the KG portions that were created by the KG creation LLM 306. The judge LLM 308 may provide the results of its evaluation and validation to the ground truth KG 310, such as for possible incorporation in the ground truth KG 310.

Next, the KG creation engine 304 may pass 313 the extracted knowledge that was obtained earlier to a creation module 314. The creation module 314 may synchronize 315 the insertion of the extracted knowledge to the ground truth KG 310 when the applicable confidence score(s) are above a specified threshold.

### D. Further Discussion

As disclosed herein, one or more embodiments may possess various useful features and aspects, although no embodiment is required to possess any of such features or aspects. The following examples are illustrative, but not exhaustive.

An embodiment may comprise and provide an integration of AI, such as one or more LLMs, and human domain expertise: An embodiment of a system combines the use of two different LLMS, namely, LLM-1 for knowledge extraction, and LLM-2 as a Judge LLM for evaluating trustworthiness, with domain expert input.

An approach according to one embodiment may ensure a robust and accurate knowledge generation process, where LLM-1 generates portions of a KG and LLM-2 assesses these portions for consistency and relevance to a ground truth KG. Human domain experts may be brought into the loop for additional validation, particularly in instances of high uncertainty, that is, low confidence.

An embodiment may to dynamically update a ground truth KG by adding new information only when that information meets a high confidence threshold, ensuring the accuracy and relevance of that information, as well as of the ground truth KG. In an embodiment, a KG may be updated in real time, or near real time, as changes occur to the network that underlies the ground truth KG.

### E. Example Methods

It is noted that any operation(s) of any of the methods disclosed herein, may be performed in response to, as a result of, and/or, based upon, the performance of any preceding operation(s). Correspondingly, performance of one or more operations, for example, may be a predicate or trigger to subsequent performance of one or more additional operations. Thus, for example, the various operations that may make up a method may be linked together or otherwise associated with each other by way of relations such as the examples just noted. Finally, and while it is not required, the individual operations that make up the various example methods disclosed herein are, in some embodiments, performed in the specific sequence recited in those examples. In other embodiments, the individual operations that make up a disclosed method may be performed in a sequence other than the specific sequence recited.

### F. Further Example Embodiments

Following are some further example embodiments. These are presented only by way of example and are not intended to limit the scope of this disclosure or the claims in any way.

Embodiment 1. A method for modeling a portion of a communication network, comprising: obtaining data concerning a configuration of a network, and passing the data to a KG (knowledge graph) creation engine; by the KG creation engine, using a KG creation LLM (large language model) to extract knowledge from the data; generating, by the KG creation LLM using the knowledge, a portion of a KG that represents a portion of the network; by a judge LLM, evaluating the portion of the KG to determine an extent to which the portion of the KG accurately represents the portion of the network; and updating a ground truth KG with the extracted knowledge when the portion of the KG has a confidence score that exceeds a threshold confidence score.

Embodiment 2. The method as recited in any preceding embodiment, wherein the network comprises a RAN (radio access network).

Embodiment 3. The method as recited in any preceding embodiment, wherein the knowledge comprises information about entities in the network, and relationships between the entities.

Embodiment 4. The method as recited in any preceding embodiment, wherein the confidence score is generated by the judge LLM.

Embodiment 5. The method as recited in any preceding embodiment, wherein the confidence score indicates the extent to which the portion of the KG accurately represents the portion of the network.

Embodiment 6. The method as recited in any preceding embodiment, wherein when the confidence score is below the threshold confidence score, the portion of the KG is passed to a human for evaluation.

Embodiment 7. The method as recited in any preceding embodiment, wherein the updating of the ground truth KG is performed by a creation module that synchronizes insertion of the extracted knowledge to the ground truth KG.

Embodiment 8. The method as recited in any preceding embodiment, wherein the ground truth KG comprises nodes that each correspond to a respective entity of the portion of the network, and also comprises edges connecting the nodes, and the edges represent relationships between the nodes.

Embodiment 9. The method as recited in any preceding embodiment, wherein the evaluating of the portion of the KG by the judge LLM comprises comparing, by the judge LLM, the portion of the KG with a corresponding portion of the ground truth KG.

Embodiment 10. The method as recited in any preceding embodiment, wherein when the confidence score is below the threshold confidence score, information is received, from a human expert, that indicates an outcome of an evaluation, by the human expert, of the portion of the KG.

Embodiment 11. A system, comprising hardware and/or software, operable to perform any of the operations, methods, or processes, or any portion of any of these, disclosed herein.

Embodiment 12. A non-transitory storage medium having stored therein instructions that are executable by one or more hardware processors to perform operations comprising the operations of any one or more of embodiments 1-10.

### G. Example Computing Devices and Associated Media

The embodiments disclosed herein may include the use of a special purpose or general-purpose computer including various computer hardware or software modules, as discussed in greater detail below. A computer may include a processor and computer storage media carrying instructions that, when executed by the processor and/or caused to be executed by the processor, perform any one or more of the methods disclosed herein, or any part(s) of any method disclosed.

As indicated above, embodiments within the scope of this disclosure also include computer storage media, which are physical media for carrying or having computer-executable instructions or data structures stored thereon. Such computer storage media may be any available physical media that may be accessed by a general purpose or special purpose computer.

By way of example, and not limitation, such computer storage media may comprise hardware storage such as solid state disk/device (SSD), RAM, ROM, EEPROM, CD-ROM, flash memory, phase-change memory (“PCM”), or other optical disk storage, magnetic disk storage or other magnetic storage devices, or any other hardware storage devices which may be used to store program code in the form of computer-executable instructions or data structures, which may be accessed and executed by a general-purpose or special-purpose computer system to implement the disclosed functionality. Combinations of the above should also be included within the scope of computer storage media. Such media are also examples of non-transitory storage media, and non-transitory storage media also embraces cloud-based storage systems and structures, although the scope of this disclosure is not limited to these examples of non-transitory storage media.

### Computer-Executable Instructions Comprise, for Example,

instructions and data which, when executed, cause a general purpose computer, special purpose computer, or special purpose processing device to perform a certain function or group of functions. As such, some embodiments may be downloadable to one or more systems or devices, for example, from a website, mesh topology, or other source. As well, the scope of this disclosure embraces any hardware system or device that comprises an instance of an application that comprises the disclosed executable instructions.

Although the subject matter has been described in language specific to structural features and/or methodological acts, it is to be understood that the subject matter defined in the appended claims is not necessarily limited to the specific features or acts described above. Rather, the specific features and acts disclosed herein are disclosed as example forms of implementing the claims.

As used herein, the term module, component, client, agent, service, engine, or the like may refer to software objects or routines that execute on the computing system. These may be implemented as objects or processes that execute on the computing system, for example, as separate threads. While the system and methods described herein may be implemented in software, implementations in hardware or a combination of software and hardware are also possible and contemplated. In the present disclosure, a ‘computing entity’ may be any computing system as previously defined herein, or any module or combination of modules running on a computing system.

In at least some instances, a hardware processor is provided that is operable to carry out executable instructions for performing a method or process, such as the methods and processes disclosed herein. The hardware processor may or may not comprise an element of other hardware, such as the computing devices and systems disclosed herein.

In terms of computing environments, embodiments may be performed in client-server environments, whether network or local environments, or in any other suitable environment. Suitable operating environments for at least some embodiments include cloud computing environments where one or more of a client, server, or other machine may reside and operate in a cloud environment.

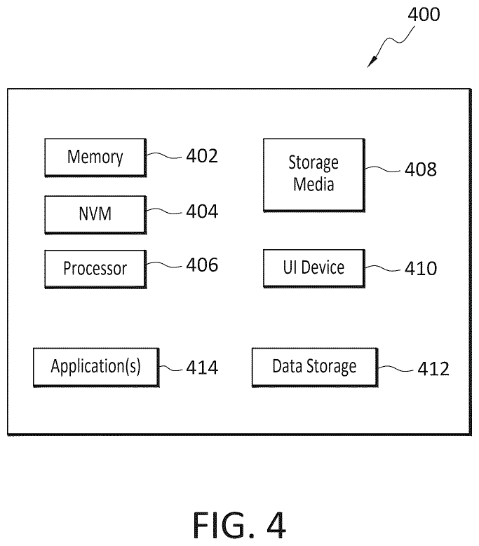

With reference briefly now to FIG. 4, any one or more of the entities disclosed, or implied, by FIGS. 2-3, and/or elsewhere herein, may take the form of, or include, or be implemented on, or hosted by, a physical computing device, one example of which is denoted at 400. As well, where any of the aforementioned elements comprise or consist of a virtual machine (VM), that VM may constitute a virtualization of any combination of the physical components disclosed in FIG. 4.

In the example of FIG. 4, the physical computing device 400 includes a memory 402 which may include one, some, or all, of random access memory (RAM), non-volatile memory (NVM) 404 such as NVRAM for example, read-only memory (ROM), and persistent memory, one or more hardware processors 406, non-transitory storage media 408, UI device 410, and data storage 412. One or more of the memory components 402 of the physical computing device 400 may take the form of solid state device (SSD) storage. As well, one or more applications 414 may be provided that comprise instructions executable by one or more hardware processors 406 to perform any of the operations, or portions thereof, disclosed herein.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The described embodiments are to be considered in all respects only as illustrative and not restrictive. All changes which come within the meaning and range of equivalency of the claims are to be embraced within their scope.

What is claimed is:

1. A method for modeling a portion of a communication network, comprising:
obtaining data concerning a configuration of a network, and passing the data to a KG (knowledge graph) creation engine;
by the KG creation engine, using a KG creation LLM (large language model) to extract knowledge from the data;
generating, by the KG creation LLM using the knowledge, a portion of a KG that represents a portion of the network;
by a judge LLM, evaluating the portion of the KG to determine an extent to which the portion of the KG accurately represents the portion of the network; and
updating a ground truth KG with the extracted knowledge when the portion of the KG has a confidence score that exceeds a threshold confidence score.

2. The method as recited in claim 1, wherein the network comprises a RAN (radio access network).

3. The method as recited in claim 1, wherein the knowledge comprises information about entities in the network, and relationships between the entities.

4. The method as recited in claim 1, wherein the confidence score is generated by the judge LLM.

5. The method as recited in claim 1, wherein the confidence score indicates the extent to which the portion of the KG accurately represents the portion of the network.

6. The method as recited in claim 1, wherein when the confidence score is below the threshold confidence score, the portion of the KG is passed to a human expert for evaluation.

7. The method as recited in claim 1, wherein the updating of the ground truth KG is performed by a creation module that synchronizes insertion of the extracted knowledge to the ground truth KG.

8. The method as recited in claim 1, wherein the ground truth KG comprises nodes that each correspond to a respective entity of the portion of the network, and also comprises edges connecting the nodes, and the edges represent relationships between the nodes.

9. The method as recited in claim 1, wherein the evaluating of the portion of the KG by the judge LLM comprises comparing, by the judge LLM, the portion of the KG with a corresponding portion of the ground truth KG.

10. The method as recited in claim 1, wherein when the confidence score is below the threshold confidence score, information is received, from a human expert, that indicates an outcome of an evaluation, by the human expert, of the portion of the KG.

11. A non-transitory storage medium having stored therein instructions that are executable by one or more hardware processors to perform operations comprising:
obtaining data concerning a configuration of a network, and passing the data to a KG (knowledge graph) creation engine;
by the KG creation engine, using a KG creation LLM (large language model) to extract knowledge from the data;
generating, by the KG creation LLM using the knowledge, a portion of a KG that represents a portion of the network;
by a judge LLM, evaluating the portion of the KG to determine an extent to which the portion of the KG accurately represents the portion of the network; and
updating a ground truth KG with the extracted knowledge when the portion of the KG has a confidence score that exceeds a threshold confidence score.

12. The non-transitory storage medium as recited in claim 11, wherein the network comprises a RAN (radio access network).

13. The non-transitory storage medium as recited in claim 11, wherein the knowledge comprises information about entities in the network, and relationships between the entities.

14. The non-transitory storage medium as recited in claim 11, wherein the confidence score is generated by the judge LLM.

15. The non-transitory storage medium as recited in claim 11, wherein the confidence score indicates the extent to which the portion of the KG accurately represents the portion of the network.

16. The non-transitory storage medium as recited in claim 11, wherein when the confidence score is below the threshold confidence score, the portion of the KG is passed to a human expert for evaluation.

17. The non-transitory storage medium as recited in claim 11, wherein the updating of the ground truth KG is performed by a creation module that synchronizes insertion of the extracted knowledge to the ground truth KG.

18. The non-transitory storage medium as recited in claim 11, wherein the ground truth KG comprises nodes that each correspond to a respective entity of the portion of the network, and also comprises edges connecting the nodes, and the edges represent relationships between the nodes.

19. The non-transitory storage medium as recited in claim 11, wherein the evaluating of the portion of the KG by the judge LLM comprises comparing, by the judge LLM, the portion of the KG with a corresponding portion of the ground truth KG.

20. The non-transitory storage medium as recited in claim 11, wherein when the confidence score is below the threshold confidence score, information is received, from a human expert, that indicates an outcome of an evaluation, by the human expert, of the portion of the KG.
